(19) United States
(12) Patent Application Publication
(10) Pub. No.: US 2012/0180850 A1
(43) Pub. Date: Jul. 19, 2012

(54) PHOTOELECTRIC CONVERSION MODULE AND METHOD OF MANUFACTURING THE SAME

(76) Inventors: Sung-Su Kim, Yongin-si (KR); Nam-Choul Yang, Yongin-si (KR); Hyun-Chul Kim, Yongin-si (KR)

(21) Appl. No.: 13/239,242

(22) Filed: Sep. 21, 2011

Related U.S. Application Data
(60) Provisional application No. 61/432,528, filed on Jan. 13, 2011.

(51) Int. Cl. H01L 31/05; H01L 31/0224

(52) U.S. Cl. 136/251; 438/66; 257/E31.124

(57) ABSTRACT

A photoelectric conversion module in which a plurality of photoelectric cells are modularized and a method of manufacturing the photoelectric conversion module with reduced number of manufacturing processes are provided.

### CROSS-REFERENCE TO RELATED APPLICATION

This application claims priority to and the benefit of U.S. Provisional Application No. 61/432,528, filed on Jan. 13, 2011, in the United States Patent and Trademark Office, the disclosure of which is incorporated herein in its entirety by reference.

### BACKGROUND

1. Field

Aspects of embodiments according to the present invention relate to a photoelectric conversion module and a method of manufacturing the same.

2. Description of Related Art

Recently, research has been conducted in various photoelectric conversion modules for converting light energy into electric energy as an energy source for replacing fossil fuel, and solar batteries for obtaining energy from sunlight are attracting attention.

From among solar batteries having various operation principles, wafer-type silicon or crystalline solar batteries using p-n junctions of semiconductors are the most popular but have high manufacturing cost because high purity semiconductor materials are used.

Unlike a silicon-based solar battery, a dye-sensitized solar battery generally includes a photosensitive dye that receives light that has a wavelength of visual light and generates excited electrons, a semiconductor material that receives the excited electrons, and an electrolyte that reacts with electrons that are returning from an external circuit. The dye-sensitized solar battery has a much higher photoelectric conversion efficiency than general solar batteries, and thus is regarded as a next-generation solar battery.

### SUMMARY

Embodiments of the present invention are directed toward a modularized photoelectric conversion module in which a plurality of photoelectric cells are arranged, so as to reduce the number of manufacturing processes of the photoelectric conversion module, and a method of manufacturing the photoelectric conversion module.

According to the embodiments of the present invention, a single substrate is used as a support for supporting a group of modularized photoelectric cells, and a photoelectric conversion module is completed by using layer forming operations that are sequentially performed on the single substrate, and thus the number of manufacturing processes may be reduced. In addition, the photoelectric cells are coupled to one another through open space between adjacent photoelectric cells, thereby omitting a conventional complicated connection structure for coupling the photoelectric cells and a manufacturing operation of manufacturing the connection structure.

According to an embodiment of the present invention, a photoelectric conversion module includes a substrate and at least two photoelectric cells. The at least two photoelectric cells are spaced from each other on the substrate, and a cell of the at least two photoelectric cells includes: a first electrode on the substrate; a sealant including at least a portion on the first electrode; and a second electrode on the sealant, the sealant together with at least one of the first electrode or the substrate, and the second electrode, enclosing an interior space of the cell; and a connection member electrically coupling the second electrode of one of the at least two photoelectric cells to the first electrode or the second electrode of a neighboring one of the at least two photoelectric cells.

The photoelectric conversion module may not include any discontinuous substrate.

The substrate of the photoelectric conversion module may be a single continuous substrate.

The second electrode may include a catalyst layer.

The second electrode may include a metal layer on the catalyst layer.

The connection member and the second electrode may be formed as a single integral piece.

The connection member may include a flexible conductive material.

The connection member may be flexibly bent and suspended over a gap between neighboring cells of the at least two photoelectric cells.

A part of the first electrode may extend beyond the sealant that surrounds the interior space of the cell.

The connection member may be electrically coupled to the part of the first electrode that extends beyond the sealant that surrounds the interior space of the cell.

The substrate may include a transparent material.

The first electrode may include: a transparent conductive layer on the substrate; and a grid electrode on the transparent conductive layer, the grid electrode including a plurality of finger electrodes that are spaced apart from each other inside the interior space of the cell.

The grid electrode may further include a collector electrode coupled with the finger electrodes, the collector electrode having at least a part outside of the interior space of the cell.

The cell may further include a semiconductor layer and an electrolyte in the interior space of the cell.

The photoelectric conversion module may further include a photosensitive dye absorbed by the semiconductor layer.

According to an embodiment of the present invention, a method is provided to manufacture a photoelectric conversion module including at least two photoelectric cells. The method includes: forming first electrodes of the at least two photoelectric cells on a common substrate, the first electrodes being spaced from each other; forming sealants on the first electrodes, each of the sealants including at least a portion on a corresponding one of the first electrodes; forming a material plate covering the at least two photoelectric cells including the sealants and the first electrodes; and separating the material plate into a plurality of electrode portions, one of the electrode portions including a second electrode, which encloses an interior space of a cell of the at least two photoelectric cells, together with a corresponding one of the sealants and at least one of the substrate or a corresponding one of the first electrodes.

The separation of the material plate may include cutting the material plate into the plurality of electrode portions by punching or stamping.

The one of the electrode portions may further include a connection member integrally formed with the second electrode as a single piece, and, during the separation of the material plate, the connection member may be bent toward the substrate to be on the first electrode of a neighboring cell of the at least two photoelectric cells.

The method may further include electrically coupling the connection member to the first electrode of the neighboring cell.

The connection member may be electrically coupled to the first electrode of the neighboring cell by welding or by using a conductive adhesive.

### BRIEF DESCRIPTION OF THE DRAWINGS

FIG. 1 is a plan view illustrating a photoelectric conversion module according to an embodiment of the present invention.

FIG. 2 is an exploded perspective view of the photoelectric conversion module of FIG. 1, according to an embodiment of the present invention.

FIG. 3 is an expanded exploded perspective view of a photoelectric cell illustrated in FIG. 2.

FIG. 4 is a cross-sectional view illustrating the photoelectric conversion module of FIG. 1 taken along the line IV-IV according to an embodiment of the present invention.

FIG. 5 is a cross-sectional view illustrating the photoelectric conversion module of FIG. 1 taken along the line V-V.

FIG. 6 is a cross-sectional view illustrating the photoelectric conversion module of FIG. 1 taken along the line IV-IV according to another embodiment of the present invention.

FIG. 7 is an exploded perspective view of the photoelectric conversion module according to another embodiment of the present invention.

FIG. 8 is a cross-sectional view illustrating the photoelectric conversion module of FIG. 7 taken along the line VII-VII according to an embodiment of the present invention.

FIG. 9 is a cross-sectional view illustrating a counter electrode and a connection member illustrated in FIG. 8.

FIGS. 10A through 10C are cross-sectional views illustrating a method of manufacturing a photoelectric conversion module according to another embodiment of the present invention.

FIG. 11 is a cross-sectional view illustrating the photoelectric conversion module of FIG. 7 taken along the line according to another embodiment of the present invention.

### DESCRIPTION OF EXEMPLARY EMBODIMENTS

The present invention will now be described more fully with reference to the accompanying drawings, in which exemplary embodiments of the invention are shown.

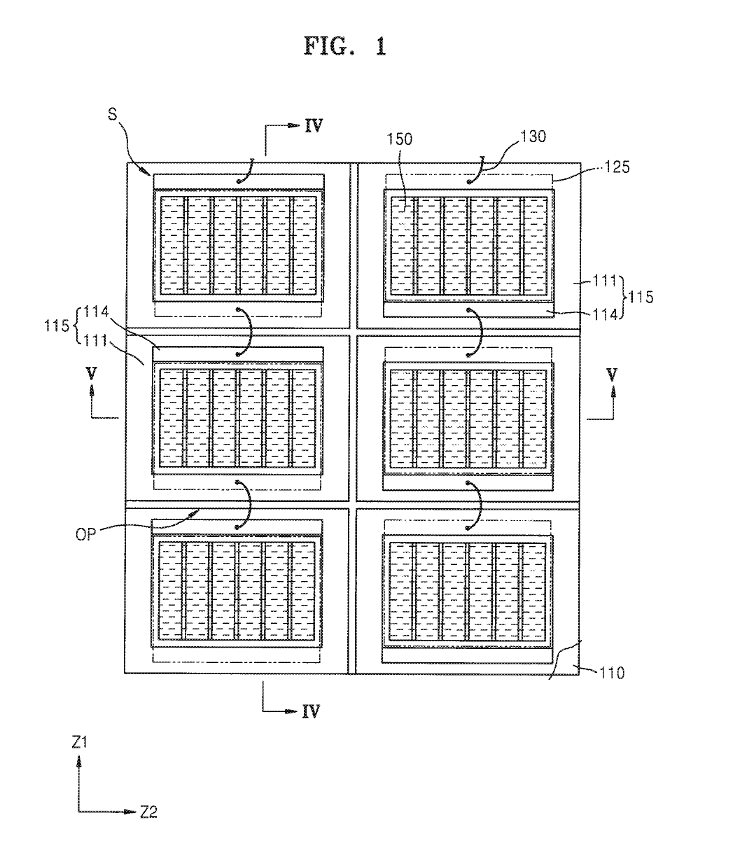

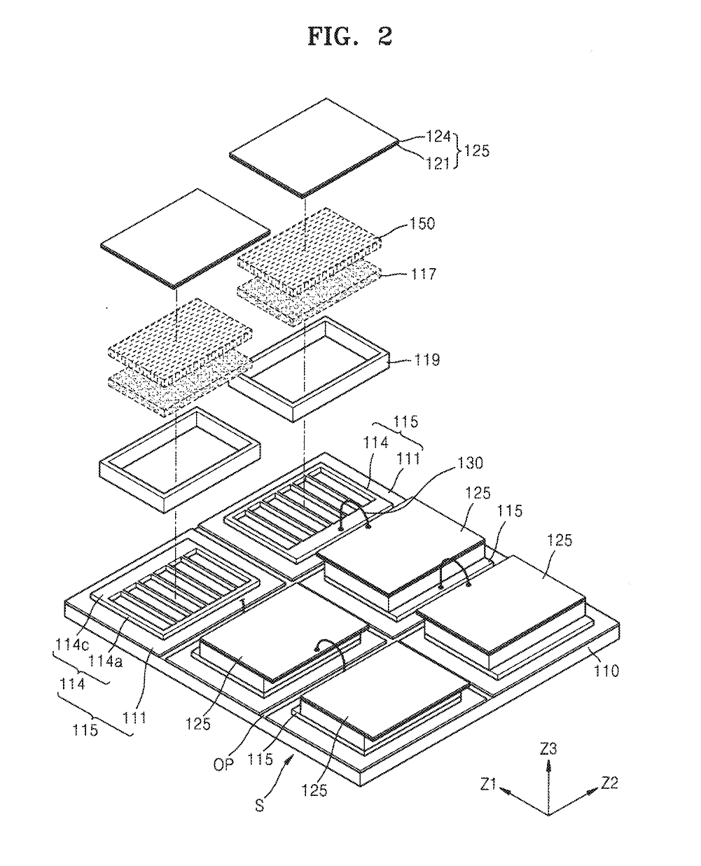

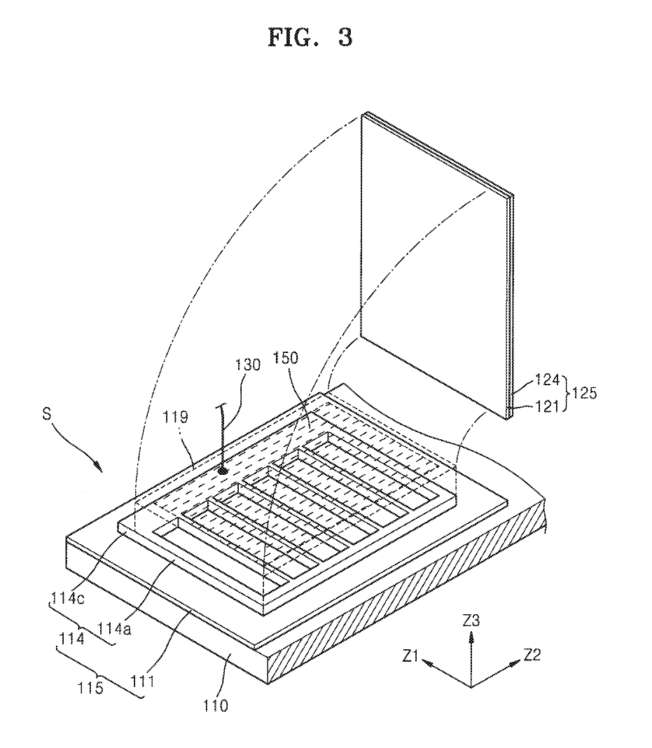

FIG. 1 is a plan view illustrating a photoelectric conversion module according to an embodiment of the present invention. FIG. 2 is an exploded perspective view of the photoelectric conversion module of FIG. 1, according to an embodiment of the present invention. FIG. 3 is an expanded exploded perspective view of a photoelectric cell illustrated in FIG. 2.

Referring to FIGS. 1 through 3, the photoelectric conversion module includes a plurality of photoelectric cells S formed on a single common substrate 110. The common substrate 110 may have a square plate shape but is not limited thereto. For example, the common substrate 110 may have any of various suitable shapes including the square shape.

A plurality of photoelectric cells S are arranged vertically and horizontally in two dimensions on the common substrate 110. For example, the plurality of photoelectric cells S may be arranged in a 3×2 matrix in vertical and horizontal directions of the common substrate 110. For example, three photoelectric cells S are arranged in a long side direction (e.g., Z1 direction) of the common substrate 110, and two photoelectric cells S are arranged in a short side direction (e.g., Z2 direction) of the common substrate 110. However, embodiments of the present invention are not limited thereto, and a number (e.g., a predetermined number) of photoelectric cells S corresponding to the total power of the photoelectric conversion module may be arranged in various suitable types of arrangement.

The photoelectric conversion module has a modular structural support including a single substrate (e.g., the common substrate 110). For example, the common substrate 110 may be formed on a light receiving surface of the photoelectric conversion module on which light is incident, and a base or substrate that would be shared by adjacent photoelectric cells S as a modular structural support is not formed at a side of the photoelectric conversion module opposite to the light receiving surface. For example, at the side of the photoelectric conversion module opposite to the common substrate 110, there is no substrate, but counter electrodes 125 are exposed. The common substrate 110 may be formed of a transparent material having a high light-transmittance. While the common substrate 110 is shared by the photoelectric cells S, the counter electrodes 125 disposed to face the common substrate 110 are respectively formed for the photoelectric cells S. That is, the counter electrodes 125 are separately formed.

According to one embodiment of the present invention, a single substrate (i.e., the common substrate 110) is used, and a layered structure is stacked on the single substrate by sequentially forming layers on the single substrate to complete a photoelectric conversion module. According to the related art, an electrode structure may be formed on each of a first substrate and a second substrate, and the first and second substrates are disposed to face each other, and a sealing member is interposed therebetween to seal the first and second substrates to each other. However, according to one embodiment of the present invention, the single common substrate 110 is used, and thus a sealing operation as described above may be omitted.

A group of the photoelectric cells S are arranged on the single common substrate 110 to be structurally modularized, and are electrically coupled to one another to be electrically modularized. Neighboring photoelectric cells S may be coupled in series or parallel to one another via a connection member 130 in order to be modularized. For example, a photoelectrode 115 and a counter electrode 125 may be coupled to each other between neighboring photoelectric cells S by using the connection member 130 to thereby connect the neighboring photoelectric cells S to one another.

An electrolyte 150 is filled inside the photoelectric cells S. The electrolyte 150 filled in the photoelectric cells S is encapsulated using a sealing member 119 disposed around a periphery (e.g., a boundary) of the photoelectric cells S. The sealing member 119 is extended along the periphery of each of the photoelectric cells S, and surrounds the electrolyte 150 so that the electrolyte 150 does not leak out. In more detail, the sealing member 119 is disposed between the common substrate 110 and the plurality of counter electrodes 125, which are separately formed. The common substrate 110 and the plurality of counter electrodes 125 are coupled to each other via the sealing member 119 to thereby encapsulate the space for accommodating the electrolyte 150. The group of photoelectric cells S are individually encapsulated, and the electrolyte 150 contained in each of the photoelectric cells S is encapsulated by the sealing member 119 that is formed exclusively for each of the photoelectric cells S. Since the photoelectric cells S are separately encapsulated, the electrolyte 150 does not flow to neighboring photoelectric cells S.

The plurality of photoelectric cells S are arranged next to each other on the common substrate 110 with open space OP therebetween. The open space OP is formed on the common substrate 110, on which a group of the photoelectric cells S are formed, and may correspond to the space between the sealing members 119 that encapsulate the neighboring photoelectric cells S and form an open space that is exposed to the outside. Also, as the open space OP is formed, the photoelectric cells S are separated from one another by the open space OP.

Inside the photoelectric cells 5, functional layers for performing photoelectric conversion may be formed. For example, the photoelectric cells S each include a semiconductor layer 117 for generating excited electrons from incident light and an electrode structure used to collect the generated electrons and direct the same to the outside. As a portion of the electrode structure, a grid pattern 114 may be formed inside the photoelectric cells S.

As illustrated in FIG. 3, the grid pattern 114 may include, for example, a plurality of finger (or line) electrodes 114a that extend in parallel to one another in a direction (e.g., a predetermined direction Z1) and a collector electrode 114c that extends in a direction (e.g., Z2 direction) across the finger electrodes 114a. A portion of the collector electrode 114c may be exposed at the outside of the photoelectric cells S surrounded by the sealing member 119, and the connection member 130 may be coupled to the exposed portion of the collector electrode 114c. However, as will be described later in more detail, the collector electrode 114c is formed as a portion of the photoelectrode 115, and various portions of the photoelectrode 115 other than the collector electrode 114c may form a contact with the connection member 130.

Neighboring photoelectric cells S are electrically coupled to one another via the connection member 130. For example, each connection member 130 may electrically couple a counter electrode 125 of a photoelectric cell S to a photoelectrode 115 of an adjacent photoelectric cell S. In more detail, a first end of the connection member 130 is coupled to the counter electrode 125 of a photoelectric cell S, and a second end of the connection member 130 is coupled to the photoelectrode 115 of an adjacent photoelectric cell S. A portion of the photoelectrode 115 is exposed outside the sealing member 119, and the connection member 130 may be coupled to the exposed portion of the photoelectrode 115.

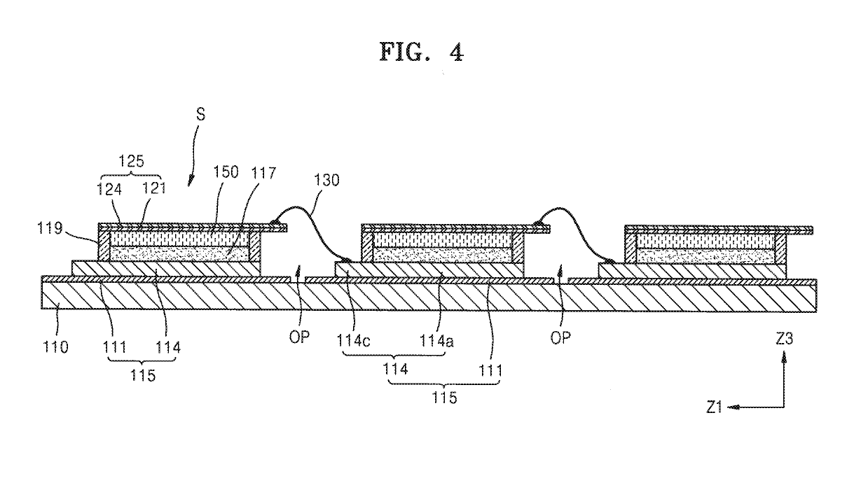

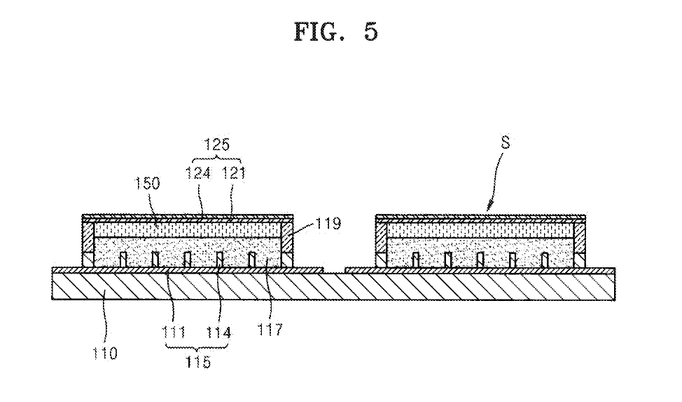

FIG. 4 is a cross-sectional view illustrating the photoelectric conversion module of FIG. 1 taken along the line IV-IV according to an embodiment of the present invention. FIG. 5 is a cross-sectional view illustrating the photoelectric conversion module of FIG. 1 taken along the line V-V. Referring to FIGS. 4 and 5, the common substrate 110 is formed as a support for supporting the group of photoelectric cells S on a modular basis; and the semiconductor layer 117, which is adsorbed with a photosensitive dye that is excited by light, and the photoelectrode 115 and the counter electrode 125, which are disposed to face each other at the light receiving surface and at the side opposite thereto with the semiconductor layer 117 interposed therebetween, are formed on the common substrate 110. Also, the electrolyte 150 is between the counter electrode 125 and the semiconductor layer 117. The group of photoelectric cells S arranged on the common substrate 110 are electrically coupled to neighboring photoelectric cells S via the connection member 130, and may be modularized via serial connection or parallel connection.

The common substrate 110 may be formed of a transparent material. In some embodiments, the common substrate 110 may be formed of a glass substrate that is formed of glass or a resin film. The resin film may have flexibility and is thus appropriate when flexibility is desired.

The photoelectrode 115 is formed on the common substrate 110 for each photoelectric cell S. A plurality of the photoelectrodes 115 are respectively formed for each of the photoelectric cells S, and are spaced apart from one another on the common substrate 110 at intervals (e.g., predetermined intervals). Since the photoelectrodes 115 are respectively formed for the photoelectric cells S, the photoelectrodes 115 are electrically separated from one another so that interference does not occur between neighboring photoelectric cells S.

The photoelectrode 115 may include a transparent conductive layer 111 and a grid pattern 114 formed on the transparent conductive layer 111. The transparent conductive layer 111 may be formed of a material having both transparency and electric conductivity, for example, a transparent conducting oxide (TCO) such as indium tin oxide (ITO), fluorine tin oxide (FTO), or antimony tin oxide (ATO). The transparent conductive layer 111 may be formed directly on the common substrate 110 and may have individual portions which may be separated from each other at a distance (e.g., a predetermined distance) to correspond to each photoelectric cell S. As will be described later in more detail, the transparent conductive layer 111 may be formed over substantially the entire surface area of the common substrate 110. Alternatively, for example, the transparent conductive layer 111 may be separated for each photoelectric cell S using an individualization process such as laser scribing.

The grid pattern 114 is used to reduce electric resistance of the photoelectrode 115, and provides a current path of low resistance to receive electrons generated due to the photoelectric conversion effect. For example, the grid pattern 114 may be formed of a metal having excellent electric conductivity, such as gold (Au), silver (Ag), aluminum (Al), etc.

As illustrated in FIG. 3, the grid pattern 114 includes a plurality of finger electrodes 114a that are formed at a photoelectric conversion area surrounded by the sealing member 119 and a collector electrode 114c that extends in a direction that crosses the finger electrodes 114a and couples the finger electrodes 114a using a single common wiring. The finger electrodes 114a may be formed of striped patterns extending in parallel in the first direction (Z1 direction), and the collector electrode 114c may extend in the second direction (Z2 direction), crossing the first direction. However, the embodiments of the present invention are not limited thereto. For example, the finger electrodes 114a may be patterned in a mesh pattern. Although not shown in the drawings, a protection layer (not shown) may be further formed on an external surface of the grid pattern 114. The protection layer (not shown) prevents the grid pattern 114 from contacting and reacting with the electrolyte 150 so as to prevent an electrode damage such as corrosion of the grid pattern 114. The protection layer (not shown) may be formed of a material that does not react with the electrolyte 150, for example, a curing material.

At least a portion of the collector electrode 114c may be exposed outside the sealing member 119 for electrically coupling neighboring photoelectric cells S. For example, the entire collector electrode 114c may be formed outside the sealing member 119 or only a portion of the collector electrode 114c may be outside the sealing member 119, and the exposed portion of the collector electrode 114c functions as a terminal portion of the photoelectrode 115. The terminal portion provides a terminal area for connection with the connection member 130 and may form a contact with the connection member 130. Referring to FIG. 4, the collector electrode 114c forms a contact with the connection member 130 as a terminal portion of the photoelectrode 115. However, the embodiments of the present invention are not limited thereto; portions of the photoelectrode 115 other than the collector electrode 114c may also form a contact with the connection member 130.

As illustrated in FIG. 4, a group of the photoelectric cells S formed on the common substrate 110 are coupled in series or parallel to one another to be modularized. For example, a counter electrode 125 and a photoelectrode 115 of adjacent photoelectric cells S may be electrically coupled to each other to form a serial connection. Here, among the group of the photoelectric cells 5, counter electrodes 125 and photoelectrodes 115 that do not contact the connection member 130 form an interface between the group of the modularized photoelectric cells S and an external circuit (not shown). For example, as illustrated in FIG. 1, the modularized photoelectric cells S may be electrically coupled to the external circuit (not shown) via photoelectric cells S disposed at a first end portion (e.g., upper end portion) of the common substrate 110. For example, a photoelectrode 115 of a photoelectric cell S and a counter electrode 125 of another photoelectric cell S disposed at a first end portion of the common substrate 110 may be directly coupled to an external circuit (not shown) or may be electrically coupled to the external circuit (not shown) via another connection terminal (not shown). However, the interface between the photoelectric conversion module and the external circuit (not shown) may be formed via photoelectric cells that are selected according to the arrangement of the photoelectric cells and according to the configuration of an external connection terminal, and is not limited as illustrated in FIG. 4.

Formation of the photoelectrode 115 will now be described in more detail with reference to FIG. 4. For example, the transparent conductive layer 111 is formed substantially on the entire common substrate 110, and then laser scribing is performed to separate the transparent conductive layer 111 for each photoelectric cell S. Then, the grid pattern 114 may be formed on each of the separated portions of the transparent conductive layer 111 to form the photoelectrode 115.

The photoelectrode 115 functions as a negative electrode of the photoelectric cells S and may have a high aperture ratio, according to one embodiment. Light that is incident through the photoelectrode 115 functions as an excitation source of the photosensitive dye adsorbed in the semiconductor layer 117, and thus photoelectric conversion efficiency may be increased by allowing as much incident light as possible.

The semiconductor layer 117 may be formed on the photoelectrode 115 to generate excited electrons from the light incident on the common substrate 110. The semiconductor layer 117 may be formed of a metal oxide from a metal such as Cd, Zn, In, Pb, Mo, W, Sb, Ti, Ag, Mn, Sn, Zr, Sr, Ga, Si, or Cr. Photoelectric conversion efficiency may be increased by adsorbing the photosensitive dye in the semiconductor layer 117. For example, the semiconductor layer 117 may be formed by coating a paste, in which semiconductor particles of a diameter of 5 to 1000 nm are dispersed, onto the common substrate 110 on which the photoelectrode 115 is formed, and heating or pressurizing the paste with a suitable amount (e.g., a predetermined amount) of heat or pressure.

The photosensitive dye adsorbed in the semiconductor layer 117 absorbs light that has transmitted through and is incident on the common substrate 110, and electrons of the photosensitive dye are excited to an excitation state from a base state. The excited electrons are transitioned to a conduction band of the semiconductor layer 117 by using an electric combination of the photosensitive dye and the semiconductor layer 117, and pass through the semiconductor layer 117 and arrive at the photoelectrode 115, and then are carried outside through the photoelectrode 115 to form a driving current that drives the external circuit (not shown).

For example, the photosensitive dye adsorbed in the semiconductor layer 117 is formed of molecules that react to a visible light band and cause a quick electron movement from a light excitation state to the semiconductor layer 117. The photosensitive dye may be in liquid form, semi-solid gel form, or solid form. For example, the photosensitive dye adsorbed in the semiconductor layer 117 may be a ruthenium-based photosensitive dye. The semiconductor layer 117 adsorbed with the photosensitive dye may be obtained by dipping the common substrate 110, on which the semiconductor layer 117 is formed, in a solution containing a suitable photosensitive dye.

The electrolyte 150 may include a Redox electrolyte including a pair of an oxidizer and a reductant, and may be either a solid electrolyte, a gel-type electrolyte, or a liquid electrolyte. The counter electrodes 125 are formed on the common electrode 110 to correspond to each photoelectric cell S. The counter electrodes 125 are respectively formed for the photoelectric cells S, and are separated from neighboring counter electrodes 125 while having an open space OP therebetween.

The counter electrode 125 may include a catalyst layer 121 and a metal layer 124 formed on the catalyst layer 121. The catalyst layer 121 may be formed of a material functioning as a reduction-catalyst to provide electrons, e.g., a metal such as platinum (Pt), gold (Au), silver (Ag), copper (Cu), aluminum (Al), etc., a metal oxide such as a tin oxide (SnO), or a carbon (C)-based material such as graphite.

The metal layer 124 is formed on the external surface of the catalyst layer 121 to protect the catalyst layer 121, and may be used to reduce electric resistance of the counter electrode 125. However, the metal layer 124 may be omitted in some embodiments. For example, the metal layer 124 may be formed of a metal such as titanium (Ti). The metal layer 124 may be formed on a surface of the catalyst layer 121 facing toward the outside. The metal layer 124 may provide a space for a terminal area for connection between neighboring photoelectric cells S. For example, a first end of the connection member 130 may be coupled to the photoelectrode 115 of a photoelectric cell S, and a second end of the connection member 130 is coupled to the metal layer 124 of a neighboring photoelectric cell 5, for example, the exposed outer surface of the metal layer 124.

The connection member 130 may be formed of a flexible conductive material. As illustrated in FIG. 4, the connection member 130 may be flexibly bent and extended while being suspended between neighboring photoelectric cells S. By forming the connection member 130 of a flexible conductive material, the handling properties of the connection member 130 may be improved, and a connecting operation of the connection member 130 may be easily performed. However, the embodiments of the present invention are not limited thereto, and the connection member 130 may be formed linearly between the neighboring photoelectric cells S to provide a shortest connection path, and as long as a connection path may be formed between the photoelectric cells 5, any suitable material in any structure may be used as the connection member 130. For example, the connection member 130 may also be formed of a rigid conductive material extending between the counter electrode 125 and the photoelectrode 115, which are to be coupled between the neighboring photoelectric cells S.

For example, the connection member 130 may include a first end coupled to the photoelectrode 115 and a second end coupled to the counter electrode 125 of a neighboring photoelectric cell S. In order for the connection member 130 to be coupled to the photoelectrode 115 or the counter electrode 125, a corresponding portion of the connection member 130 to be coupled to the photoelectrode 115 or the counter electrode 125 may be thermally welded, or a conductive adhesive (not shown) may be attached to the corresponding portion of the connection member 130. For example, the connection member 130 may be welded to the photoelectrode 115 or the counter electrode 125 by laser welding. Alternatively, an anisotropic conductive film (not shown) may be interposed, and an end portion of the connection member 130 may be pressurized on the photoelectrode 115 or the counter electrode 125 for forming electrical connection with the connection member 130.

Referring to FIG. 4, the photoelectrode 115 and the counter electrode 125 of neighboring photoelectric cells S are coupled to each other such that all photoelectric cells S arranged on the common substrate 110 are serially coupled; however, the embodiments of the present invention are not limited thereto, and for example, the photoelectrodes 115 of the neighboring photoelectric cells S may be coupled to one another, and the counter electrodes 125 of the neighboring photoelectric cells S may be coupled to one another so that all photoelectric cells S are coupled in parallel. Also, serial connection and parallel connection may be used at the same time such that some of the photoelectric cells S on the common substrate 110 may be serially coupled, and the rest of the photoelectric cells S may be coupled in parallel.

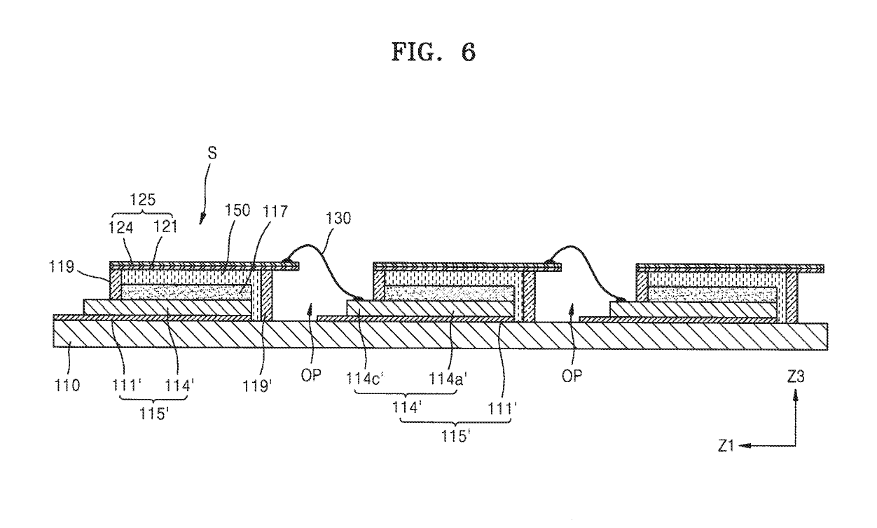

FIG. 6 is a cross-sectional view illustrating the photoelectric conversion module of FIG. 1 taken along the line IV-IV according to another embodiment of the present invention. The embodiment shown in FIG. 6 is similar to the embodiment shown in FIG. 4. Therefore, only the relevant differences between these embodiments will be described, and redundant description of the same elements will be omitted.

In FIG. 6, a photoelectrode 115′ may include a transparent conductive layer 111′ and a grid pattern 114′ formed on the transparent conductive layer 111′. The grid pattern 114′ includes a plurality of finger electrodes 114a′ that are formed at a photoelectric conversion area surrounded by a sealing member 119 and a collector electrode 114c′ that extends in a direction that crosses the finger electrodes 114a′ and couples the finger electrodes 114a′ using a single common wiring. Different from the embodiment shown in FIG. 4, the transparent conductive layer 111′ and the grid pattern 114′ do not completely cover an area of the common substrate 110 corresponding to the photoelectric cell S. That is, a portion of the sealing member 119 is on the grid pattern 114′, and another portion of the sealing member 119′ is on the common substrate 110, but not on the grid pattern 114′.

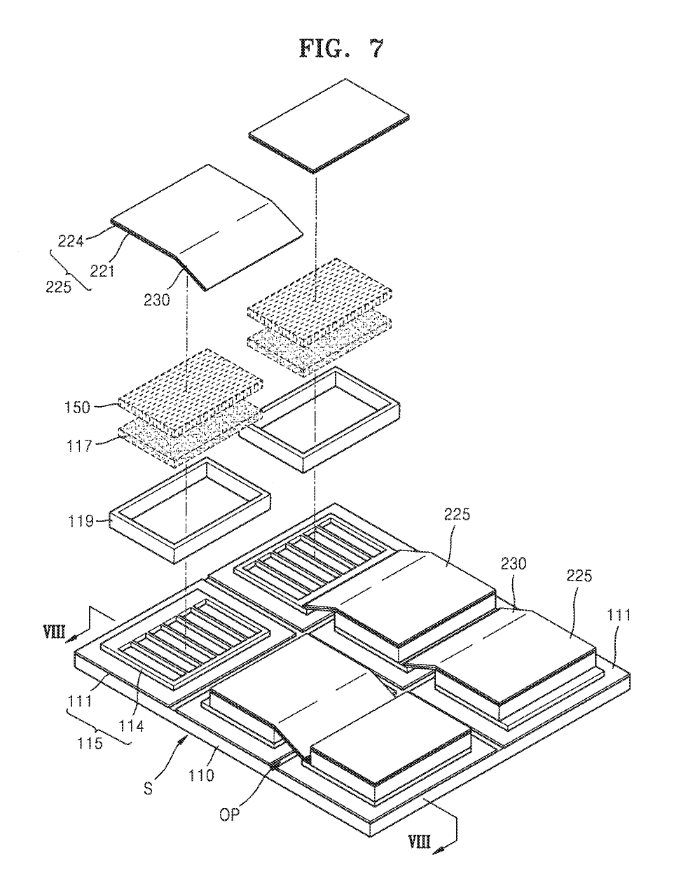

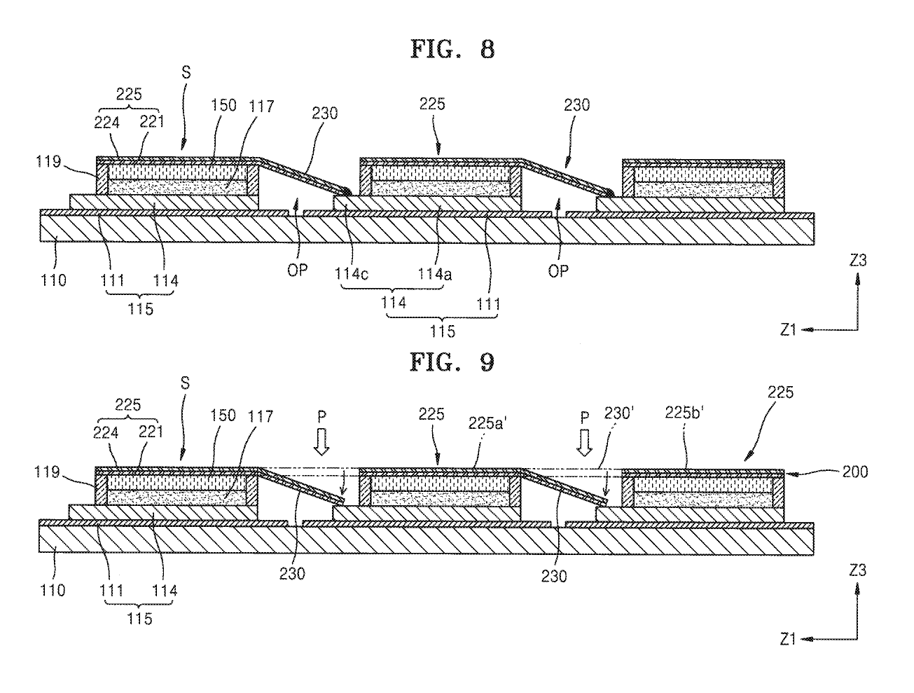

FIG. 7 is an exploded perspective view of a photoelectric conversion module according to another embodiment of the present invention. FIG. 8 is a cross-sectional view illustrating the photoelectric conversion module of FIG. 7 taken along the line VII-VII according to an embodiment of the present invention.

Referring to FIGS. 6 and 7, the photoelectric conversion module includes a common substrate 110 that structurally supports a group of photoelectric cells S, a plurality of photoelectrodes 115, a plurality of semiconductor layers 117, an electrolyte 150, and a plurality of counter electrodes 225 that are formed separately from one another on the common substrate 110. For example, the photoelectric conversion module includes the common substrate 110 at one side, for example, on a light receiving surface, and the separately formed counter electrodes 225 at the side opposite to the light receiving surface.

The group of photoelectric cells S are electrically coupled to one another via a connection member 230. For example, the group of photoelectric cells S are coupled in series or parallel using the connection member 230 that electrically couples the photoelectrodes 115 and the counter electrodes 225 of the neighboring photoelectric cells S to be in a modularized structure. The connection member 230 may be integrally extended from each of the counter electrodes 225, and may be extended from the counter electrodes 225 to be coupled to the photoelectrodes 115 of the adjacent photoelectric cells S, respectively.

The connection member 230 and the counter electrode 225 may be formed from the same raw material plate. Like the counter electrode 225, the raw material plate may be formed as a stack including a catalyst layer 221 and a metal layer 224. A portion of the raw material plate is processed to become a connection member 230, and the rest of the raw material plate is processed to function as the counter electrode 225. The connection member 230 and the counter electrode 225 are integrally formed using a single operation, and thus the number of operations is significantly reduced as compared to when they are formed separately.

For example, the counter electrodes 225 are respectively formed for the photoelectric cells S from a single raw material plate, and the raw material plate is cut to be separated into the counter electrodes 225. Here, separated portions of the raw material plate are used as the connection members 230.

The counter electrodes 225 may each include the catalyst layer 221 and the metal layer 224 formed on the catalyst layer 221. The catalyst layer 221 may be formed of a material functioning as a reduction catalyst for providing electrons, e.g., a metal such as platinum (Pt), gold (Au), silver (Ag), copper (Cu), aluminum (Al), etc., a metal oxide such as a tin oxide (SnO), or a carbon (C)-based material such as graphite.

The metal layer 224 is formed on the external surface of the catalyst layer 221 to protect the catalyst layer 221, and may be used to reduce electric resistance of the counter electrode 225. However, the metal layer 224 may be omitted in some embodiments. For example, the metal layer 224 may be formed of a metal such as titanium (Ti).

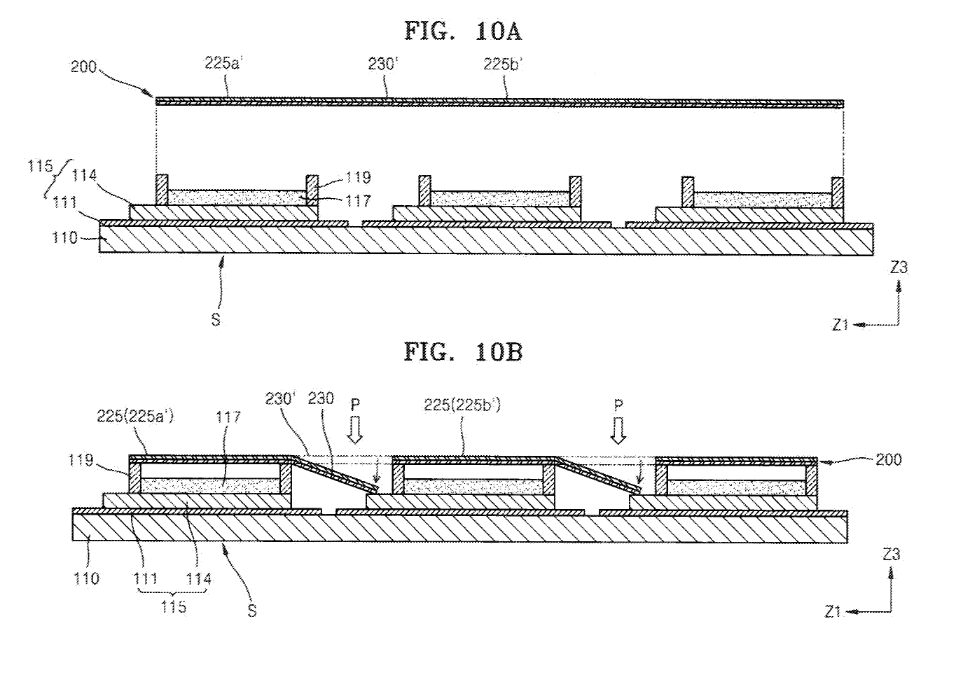

FIG. 9 is a cross-sectional view illustrating the counter electrodes 225 and the connection members 230 illustrated in FIG. 8. The manufacture of the photoelectric conversion module will now be described with reference to FIG. 9. First, various functional layers are sequentially formed on the common substrate 110. For example, a photoelectrode 115 and a semiconductor layer 117 are formed for each photoelectric cell S, and a raw material plate 200 is disposed on a sealing member 119. The raw material plate 200 is a single sheet member that is not separated for each photoelectric cell S, and the raw material plate 200 covers and extends across the photoelectric cells S.

The raw material plate 200 includes electrode portions 225a′ and 225b′ corresponding to each of the photoelectric cells S and connection portions 230′ formed between each photoelectric cell S. One connection portion 230′ is disposed between the electrode portions 225a′ and 225b′; for convenience of description, an electrode portion coupled with the connection portion 230′ will be referred to as a first electrode 225a′, and an electrode portion to be disconnected from the connection portion 230′ will be referred to as a second electrode portion 225b′. Accordingly, the first and second electrode portions 225a′ and 225b′ are formed at opposite sides of a single connection portion 230′, and the first electrode portion 225a′ may be the second electrode portion 225b′ in regard to another connection portion 230′. Thus the first and second electrode portions 225a′ and 225b′ are relative terms. Hereinafter, an exemplary connection portion 230′ will be described as an example.

A plurality of counter electrodes 225 are formed from the raw material plate 200 that is disposed across the photoelectric cells S; the counter electrodes 225 may be separated by cutting the raw material plate 200. For example, the raw material plate 200 is punched or stamped to be separated into the counter electrodes 225. As illustrated in FIG. 9, when the raw material plate 200 is punched, the connection portion 230′ is curved or bent downward due to a punching pressure P. Then, the connection portion 230′ is maintained in physical connection with the first connection portion 225a′ on a first side of the connection portion 230′, but is physically disconnected from a second connection portion 225b′ on a second side of the connection portion 230′, and is thus separated therefrom. The first electrode portion 225a′ on the first side and the second electrode portion 225b′ on the second side form counter electrodes 225 each belonging to different photoelectric cells S. The connection portion 230′ forms a connection member 230 that electrically couples the neighboring photoelectric cells S. “Bend” or “bent” as used in this application refers to forcing an object from a straight form into a curved or angular one, or from a curved or angular form into some different form.

In more detail, the connection portion 230′ extends from the first connection portion 225a′ on the first side to the photoelectrode 115 of an adjacent photoelectric cell 5, and finally forms the connection member 230 that electrically couples the counter electrodes 225 formed from the first electrode portion 225a′ and the photoelectrode 115 of a neighboring photoelectric cell S. For example, the connection portion 230′ may be curved or bent from the first connection portion 225a′ on the first side and extend downward in a diagonal direction, and may have a first end coupled to the first electrode portion 225a′ and a second end coupled to the photoelectrode 115 of a neighboring photoelectric cells S.

When punching or stamping the raw material plate 200, a punching pressure P may be partially applied to the connection portion 230′. For example, when the connection portion 230′ is punched, the connection portion 230′ may be bent around a boundary of the first connection portion 225a′ at a first side where bonding intensity is relatively higher, and may be cut off at a boundary of the second connection portion 225b′ at a second side where bonding intensity is relatively lower, and may be separated from the second connection portion 225b′ at the second side. A cutting line (not shown) may be formed in the raw material plate 200 such that fracture is easily created by the punching pressure P. The cutting line (not shown) may be formed between the connection portion 230′ and the second electrode portion 225b′ to define an area between the connection portion 230′ and the second electrode portion 225b′.

When punching the raw material plate 200, the connection portion 230′ separated from the second electrode portion 225b′ is bent downward to be near the neighboring photoelectrode 115. For example, an end portion of the connection portion 230′ may be mounted on the photoelectrode 115 or may be at least near the photoelectrode 115. To couple the connection portion 230′ and the photoelectrode 115, for example, a conductive adhesive (not shown) such as an anisotropic conductive film may be interposed between the connection portion 230′ and the photoelectrode 115, and the connection portion 230′ may be pressed onto the photoelectrode 115, thereby electrically coupling the connection portion 230′ and the photoelectrode 115 to each other. Alternatively, the connection portion 230′ and the photoelectrode 115 may be electrically coupled to each other by thermal welding using an external energy source.

As described above, by a single operation of punching the raw material plate 200, the counter electrodes 225 of each of the photoelectric cells S may be separated, and the connection members 230 between neighboring photoelectric cells S may be formed at the same time. Here, at least two individual operations may be completed in one operation, that is, they may be performed together by a simplified operation like punching. Also, since the counter electrodes 225 and the connection members 230 are formed using the single raw material plate 200, the material costs may be reduced, and since the counter electrodes 225 and the connection members 230 are integrally formed, they may be bonded more firmly.

FIGS. 9A through 9C are cross-sectional views illustrating a method of manufacturing a photoelectric conversion module according to another embodiment of the present invention.

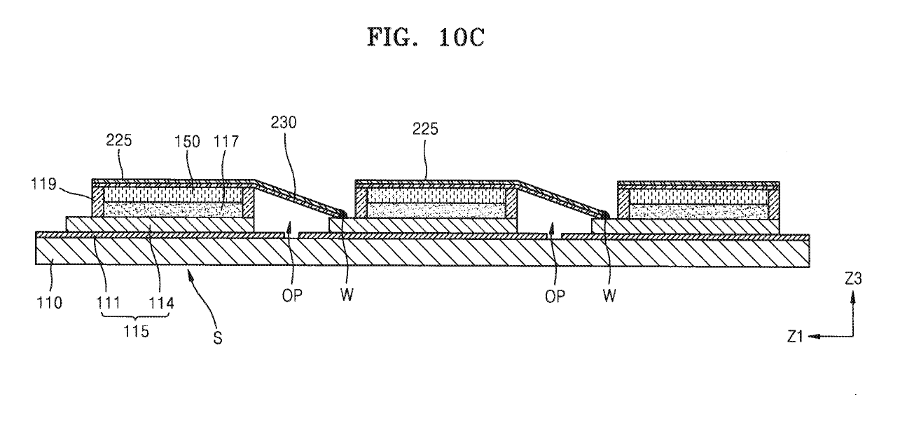

First, referring to FIG. 10A, a common substrate 110 is formed. The common substrate 110 is a support for a group of modularized photoelectric cells S, and may be formed of a glass substrate that is formed of glass or a resin film.

Next, functional layers for performing photoelectric conversion are sequentially formed on the common substrate 110. The functional layers include a semiconductor layer 117 for receiving light to generate excited electrons, and electrode structures that collect and direct the generated electrons outside. For example, the common substrate 110 may be formed of a single base substrate that is commonly formed for a group of photoelectric cells S, and the functional layers may be separately formed for each of the photoelectric cells S so that photoelectric conversion of each photoelectric cell S can be performed independently.

In more detail, a transparent conductive layer 111 may be formed over substantially the entire surface of the common substrate 110, and then may be separated for each photoelectric cell S by using laser scribing. For example, the transparent conductive layer 111 may be formed of a TCO such as ITO, FTO, or ATO.

Next, a grid pattern 114 may be formed on each of the separated portions of the transparent conductive layer 111, and accordingly, a photoelectrode 115 including the transparent conductive layer 111 and the grid pattern 114 may be formed. The grid pattern 114 may be formed of a metal having excellent electric conductivity, such as gold (Au), silver (Ag), aluminum (Al), etc. to supplement conductivity of the transparent conductive layer 111; however, the grid pattern 114 may not be formed in some embodiments.

Next, the semiconductor layer 117 adsorbed with a photosensitive dye is formed on the photoelectrode 115. For example, the semiconductor layer 117 may be formed by coating a paste, in which semiconductor particles are dispersed, onto the common substrate 110 on which the photoelectrode 117 is formed, and heating or pressurizing the paste. Then, the common substrate 110, on which the semiconductor layer 117 is formed, may be dipped into a solution containing a photosensitive dye to adsorb the photosensitive dye into the semiconductor layer 117.

Next, a sealing member 119 is formed along a periphery (e.g., a circumference) of each photoelectric cell S. The sealing member 119 may be formed of a glass frit paste. As will be described later, after counter electrodes 225 or a raw material plate 200, from which the counter electrodes 225 are to be formed, is assembled, the sealing member 119 may be hardened by using an external heat source (not shown) such as a laser.

Next, the counter electrodes 225 are formed on the other side of the photoelectric conversion module. First, a raw material plate 200 having a suitable size for covering at least two photoelectric cells S is formed.

The raw material plate 200 is separated, for example, by punching, into counter electrodes 225, and portions of the raw material plate 200 that do not form the counter electrodes 225 function as connection members 230. In more detail, the raw material plate 200 includes electrode portions 225a′ and 225b′ respectively corresponding to the photoelectric cells S and connection portions 230′ that are formed between the photoelectric cells S. Through the individualization operation of the raw material plate 200, which will be described later in more detail, the electrode portions 225a′ and 225b′ respectively form the counter electrodes 225 of the photoelectric cells S, and the connection portions 230′ form the connection members 230 that electrically couple neighboring photoelectric cells S. For example, like the counter electrodes 225, the raw material plate 200 may be formed of a stack including a catalyst layer 221′ and a metal layer 224′. The raw material plate 200 is disposed at the other side of the photoelectric conversion module; for example, one surface of the raw material plate 200 on which the catalyst layer 221′ is formed is disposed to face the inside, and the other surface of the raw material plate 200 on which the metal layer 224′ is formed is disposed to face the outside.

Next, the sealing member 119 is hardened so as to be firmly fixed between the common substrate 110 and the raw material plate 200. For example, the hardening operation may be performed by using an external heat source such as a laser (not shown) to the sealing member 119, and a laser-absorbing material may be contained in the sealing member 119.

Next, as illustrated in FIG. 10B, the raw material plate 200 is separated. For example, the raw material plate 200 is punched to be separated into respective counter electrodes 225. The electrode portions 225a′ and 225b′ of the raw material plate 200 form the counter electrodes 225, and the connection portions 230′ of the raw material plate 200 form the connection members 230. The connection portion 230′ of the raw material plate 200 is bent downward by a punching pressure P to be mounted on a neighboring photoelectrode 115 or to be near the photoelectrode 115, and forms the connection member 230 that electrically couples neighboring photoelectric cells S. The connection member 230 extends from a first end coupled to the counter electrode 225 to a neighboring photoelectric cell 5, and a second end of the connection member 230 is mounted on the photoelectrode 115 of an adjacent photoelectric cell S or is disposed near the photoelectrode 115.

Next, as illustrated in FIG. 10C, the neighboring photoelectric cells S are electrically coupled to one another by using the connection member 230. For example, a first end of the connection member 230 is integrally coupled to the counter electrode 225, and thus an additional connecting operation is not required because the connection member 230 and the counter electrode 225 are integrally formed as a single piece. In this operation, the second end of the connection member 230 is coupled to the photoelectrode 115. For example, the second end of the connection member 230 is thermally welded to the photoelectrode 115 by using an external heat source such as a laser (not shown), or a conductive adhesive such as an anisotropic conductive film (not shown) may be interposed and the connection member 230 may be pressurized on the photoelectrode 115 to electrically couple the connection member 230 and the photoelectrode 115. In FIG. 10C, a reference numeral W indicates a contact formed on the photoelectrode 115 by the second end of the connection member 230.

Next, an electrolyte 150 is filled into each photoelectric cell S through an electrolyte inlet (not shown). For example, the electrolyte inlet (not shown) may be formed in the common substrate 110, and when filling of the electrolyte 150 is completed, the electrolyte inlet (not shown) may be encapsulated or sealed.

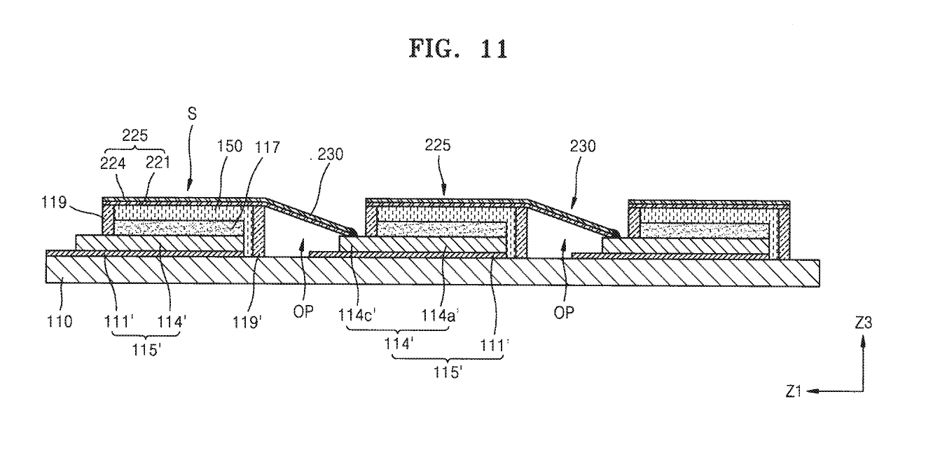

FIG. 11 is a cross-sectional view illustrating the photoelectric conversion module of FIG. 7 taken along the line according to another embodiment of the present invention. The embodiment shown in FIG. 11 is similar to the embodiment shown in FIG. 8. Therefore, only the relevant differences between these embodiments will be described, and redundant description of the same elements will be omitted.

In FIG. 11, the photoelectric conversion module includes a plurality of photoelectrodes 115′. The photoelectrode 115′ may include a transparent conductive layer 111′ and a grid pattern 114′ formed on the transparent conductive layer 111′. The grid pattern 114′ includes a plurality of finger electrodes 114a′ that are formed at a photoelectric conversion area surrounded by a sealing member 119 and a collector electrode 114c′ that extends in a direction that crosses the finger electrodes 114a′ and couples the finger electrodes 114a′ using a single common wiring. Different from the embodiment shown in FIG. 8, the transparent conductive layer 111′ and the grid pattern 114′ do not completely cover an area of the common substrate 110 corresponding to the photoelectric cell S. That is, a portion of the sealing member 119 is on the grid pattern 114′, and another portion of the sealing member 119′ is on the common substrate 110, but not on the grid pattern 114′.

According to the embodiments of the present invention, a single substrate, that is, the common substrate 110, is used, and a plurality of layers are sequentially formed on the single substrate to stack a layered structure, thereby completing a photoelectric conversion module. Accordingly, as compared to the related art, operations of disposing first and second substrates, on which electrode structures are formed, so as to face each other, and interposing a sealing member therebetween to seal the first and second substrates may be omitted. In the above-described sealing operation in the related art, functional layers formed on each of the first and second substrates are vertically aligned, and moreover, a special equipment is used to thermally pressurize the layers. Thus, when the sealing operation is omitted as shown in the exemplary embodiments of the present invention, the number of operations is reduced, and moreover, the total manufacturing costs may be reduced. The sealing operation is the final operation in which modularization is substantially completed. Thus, the sealing operation is strictly controlled, and errors generated during the sealing operation may result in wasting the previous operations for which the costs are already incurred. Thus, by omitting the sealing operation, such problems may be prevented.

According to the embodiments of the present invention, the photoelectric cells S are electrically coupled to one another through open space OP interposed between neighboring photoelectric cells S. That is, the neighboring photoelectric cells S are coupled to one another via the connection member 130 or 230 such as a slender wire extended through the open space OP, thereby simplifying the connection structure of the photoelectric cells S and increasing convenience of the connecting operation. Thus, a complicated connection structure for electrically coupling a group of modularized photoelectric cells to one another or operations for manufacturing the complicated connection structure may be omitted.

According to the embodiments of the present invention, the plurality of photoelectric cells S that are formed on the common substrate 110 are arranged next to one another while having the open space OP therebetween. The open space OP refers to the space between the sealing members 119 that encapsulates each photoelectric cell S on the common substrate 110, on which the group of photoelectric cells S are arranged, which forms an exposed space opened to the outside. The open space OP is fluidly connected to the outside. For example, impurity gas, which may be generated when forming the sealing members 119 and/or sealing the sealing members 119, may be completely discharged through this open space OP to the outside and thus may not be accumulated as internal pressure which may induce voids in the sealing members 119, etc.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

EXPLANATION OF REFERENCE NUMERALS DESIGNATING
SOME ELEMENTS OF THE DRAWINGS

| | |
|---|---|
| 110: common substrate | 111: transparent conductive layer |
| 114: grid pattern | 114a: finger electrode |
| 114c: collector electrode | 115: photoelectrode |
| 117: semiconductor layer | 119: sealing member |
| 121, 221, 221′: catalyst layer | 124, 224, 224′: metal layer |
| 125, 225: counter electrode | 130, 230: connection member |
| 150: electrolyte | 200: raw material plate |
| 225a′: first electrode portion | 225b′: second electrode portion |
| 230′: connection portion | S: photoelectric cell |
| P: punching pressure | OP: open space |

What is claimed is:

1. A photoelectric conversion module comprising:
a substrate;
at least two photoelectric cells spaced from each other on the substrate, a cell of the at least two photoelectric cells comprising:
a first electrode on the substrate;
a sealant comprising at least a portion on the first electrode; and
a second electrode on the sealant, the sealant together with at least one of the first electrode or the substrate, and the second electrode, enclosing an interior space of the cell; and
a connection member electrically coupling the second electrode of one of the at least two photoelectric cells to the first electrode or the second electrode of a neighboring one of the at least two photoelectric cells.

2. The photoelectric conversion module of claim 1, wherein the photoelectric conversion module does not comprise any discontinuous substrate.

3. The photoelectric conversion module of claim 2, wherein the substrate of the photoelectric conversion module is a single continuous substrate.

4. The photoelectric conversion module of claim 1, wherein the second electrode comprises a catalyst layer.

5. The photoelectric conversion module of claim 4, wherein the second electrode comprises a metal layer on the catalyst layer.

6. The photoelectric conversion module of claim 1, wherein the connection member and the second electrode are formed as a single integral piece.

7. The photoelectric conversion module of claim 1, wherein the connection member comprises a flexible conductive material.

8. The photoelectric conversion module of claim 7, wherein the connection member is flexibly bent and suspended over a gap between neighboring cells of the at least two photoelectric cells.

9. The photoelectric conversion module of claim 1, wherein a part of the first electrode extends beyond the sealant that surrounds the interior space of the cell.

10. The photoelectric conversion module of claim 9, wherein the connection member is electrically coupled to the part of the first electrode that extends beyond the sealant that surrounds the interior space of the cell.

11. The photoelectric conversion module of claim 1, wherein the substrate comprises a transparent material.

12. The photoelectric conversion module of claim 1, wherein the first electrode comprises:
a transparent conductive layer on the substrate; and
a grid electrode on the transparent conductive layer, the grid electrode comprising a plurality of finger electrodes that are spaced apart from each other inside the interior space of the cell.

13. The photoelectric conversion module of claim 12, wherein the grid electrode further comprises a collector electrode coupled with the finger electrodes, the collector electrode having at least a part outside of the interior space of the cell.

14. The photoelectric conversion module of claim 1, the cell further comprising a semiconductor layer and an electrolyte in the interior space of the cell.

15. The photoelectric conversion module of claim 14, further comprising a photosensitive dye absorbed by the semiconductor layer.

16. A method of manufacturing a photoelectric conversion module comprising at least two photoelectric cells, the method comprising:
forming first electrodes of the at least two photoelectric cells on a common substrate, the first electrodes being spaced from each other;
forming sealants on the first electrodes, each of the sealants comprising at least a portion on a corresponding one of the first electrodes;
forming a material plate covering the at least two photoelectric cells including the sealants and the first electrodes; and
separating the material plate into a plurality of electrode portions, one of the electrode portions comprising a second electrode, which encloses an interior space of a cell of the at least two photoelectric cells, together with a corresponding one of the sealants and at least one of the substrate or a corresponding one of the first electrodes.

17. The method of claim 16, wherein the separation of the material plate comprises cutting the material plate into the plurality of electrode portions by punching or stamping.

18. The method of claim 16, wherein the one of the electrode portions further comprises a connection member integrally formed with the second electrode as a single piece, and
wherein during the separation of the material plate, the connection member is bent toward the substrate to be on the first electrode of a neighboring cell of the at least two photoelectric cells.

19. The method of claim 18, further comprising electrically coupling the connection member to the first electrode of the neighboring cell.

20. The method of claim 18, wherein the connection member is electrically coupled to the first electrode of the neighboring cell by welding or by using a conductive adhesive.
